(19) United States
(12) Patent Application Publication
(10) Pub. No.: US 2018/0238974 A1
(43) Pub. Date: Aug. 23, 2018

(54) Gradient Field Optically Pumped Magnetometer

(71) Applicant: QuSpin, Inc., Louiville, CO (US)

(72) Inventors: Vishal Shah, Westminster, CO (US); Svenja Knappe, Boulder, CO (US); Kenneth Jeramiah Hughes, Lafayette, CO (US); Orang Alem, Lafayette, CO (US); James Osborne, Broomfield, CO (US); Jeffrey Orton, Fort Collins, CO (US)

(73) Assignee: QuSpin Inc., Louisville, CO (US)

(21) Appl. No.: 15/495,491

(22) Filed: Apr. 24, 2017

Related U.S. Application Data
(60) Provisional application No. 62/460,292, filed on Feb. 17, 2017.

(51) Int. Cl. G01R 33/26; G01R 33/32

(52) U.S. Cl. CPC G01R 33/26; G01R 33/323

(57) ABSTRACT

A system and method to measure a magnetic gradient field with an optically-pumped magnetometer is described. Atoms are spin polarized at two locations. Larmor frequencies are, induced and the spin frequency is detected. The frequencies are proportional to the total magnetic field at the locations of the atoms. The magnetic field gradient is extracted from the beat frequency of the two Larmor frequencies.

The following application is an application for patent under 35 USC 111 (a). This application claims priority to U.S. Provisional Application No. 62/460,292 filed Feb. 17, 2017 of common title and inventorship. This invention was made with government support of Defense Advanced Research Projects Agency Contract #D16PC00195. The government has certain rights in the invention.

### FIELD OF INVENTION

This disclosure relates to the field of magnetic gradient field sensing, specifically a system and method thereof.

### BACKGROUND

DC magnetic field measurements with femtotesla level resolution require highly sensitive magnetometers, such as Superconducting Quantum Interference Device (SQUID) magnetometers. SQUIDs must be cooled to cryogenic temperatures, and the technologies involved in cooling are complex, bulky, and expensive. This has proven to be a major roadblock in the mass market commercialization of SQUID technologies for many promising remote sensing applications in both the civilian and defense sector. Recently, advances in the optically pumped magnetometer (OPM) technology, also called atomic magnetometers, optical magnetometers, or optical atomic magnetometers, have led to the development of compact magnetic OPM sensors that operate without the need for cryogenic cooling and with the same sensitivity as the SQUID magnetometers (Dang et al., Appl. Phys. Lett. 97, 151110, 2010). Because OPMs do not need cryogenic cooling to operate, the cost and complexity associated with OPMs is significantly lower and enables the operation in remote environments, where maintaining a supply of cryogenics is difficult. In addition, thanks to the small size and weight of OPMs, they provide a greater flexibility for deployment in a wide range of applications.

Optically pumped magnetometers operate on the principle that electron or proton spins of atoms precess around an external magnetic field B_{Earth} at a distinct frequency, called the Larmor frequency ω_{L}, which is proportional to the magnitude of the field given by ω_{L}=γB_{Earth}, where γ is the gyromagnetic ratio. If light passes through a spin-polarized sample of atoms, the light polarization and amplitude can get modulated at the precession frequency of the atoms.

The are two classes of OPMs for DC magnetic field measurements: scalar OPMs and zero-field OPMs. A detailed description of different types of optically-pumped magnetometers and their applications has been published before, for example in an article by Budker and Romalis (Budker, D. & Romalis, M., Nat. Phys. 3, 227, 2007). The zero-field OPMs can reach very high sensitivity when operating in a regime where decoherence due to spin-exchange collisions is suppressed (Happer, W. & Tam, A. C. Phys. Rev. A 16, 1877, 1977), also known as the spin-exchange relaxation free (SERF) regime (Allred, J. C. et al., Phys. Rev. Lett. 89, 130801, 2002). Scalar sensors have reached sensitivity in the femtotesla level as well (Sheng, D. et al., Phys. Rev. Lett. 110, 160802, 2013), but so far only in large laboratory settings with highly complex setups or in very large vapor cells. Zero-field OPM sensors with high sensitivities have been implemented into compact sensors, but major limitations restrict their use including: (1) To reach very high sensitivity, OPMs must operate in a very low ambient magnetic field environment, and (2) OPMs are pure magnetometers making them highly susceptible to ubiquitous magnetic noise. For these two reasons, the zero-field OPMs can be used only in a magnetically-shielded environment in which the background field is nearly zero and the background magnetic noise is very low.

A standard way to solve the problem of ambient magnetic field noise is the implementation of gradiometers, where the magnetic field in two locations is measured and subtracted. The output is then the magnetic field gradient, which means the field difference divided by the separation of the two locations, also called the baseline of the gradiometer. In SQUIDs, intrinsic gradiometers are created by use of two oppositely-wound pick-up loops in series. In OPMs, most gradiometers have been implemented by sending the same probe laser beam through two sections of the same vapor cell and subtracting the outputs, but intrinsic gradiometers have also been demonstrated in the laboratory (Wasilewski, W., et al. Phys. Rev. Lett. 104, 133601, 2010), where both pump and probe lasers pass consecutively through two separate vapor cells. While this scheme has proven good performance, it requires precise tuning of the parameters in both vapor cells, which can be a tedious task.

### SUMMARY OF THE INVENTION

Here we describe a new gradiometer that can reach very high sensitivities, operate in high ambient magnetic fields, and suppresses ambient magnetic noise. The disclosed device is an improvement on the prior art invention of a Free Precession magnetometer (FP). The FP magnetometer concept is commonly employed in proton magnetometers and by the low-field Nuclear Magnetic Resonance (NMR) community. Very high sensitivities have been demonstrated with this approach even in small cells at room temperature (K. Jensen et al., Scientific Reports 6, 29638, 2016).

In prior art, Dehmelt in 1957 (Dehmelt, Phys. Rev. 105, 1924, 1957) demonstrated the concept that the precession frequency of atomic spins can be monitored through the transmission of light perpendicular to the axis of precession. This can be used to monitor the magnetic field at the location of the atoms, which is proportional to the precession frequency. Kukolich, 1968, (S. Kukolich, Am. J. Phys. 36, 919, 1968) extended this concept from spin ½ to spin 1 and spin 2 systems. There is a large body of prior art that uses this concept in magnetometers that are based on the free-precession of atomic electron spins in alkali atoms (C. Bowers et al., Phys. Rev. A 46, 7042, 1992; J. Skalla et al., J. Opt. Soc. Am. B 12, 772, 1995; S. Seltzer et al., Phys. Rev. A 75, 051407, 2007; C. Gemmel at al., Eur. Phys. J. D 57, 303, 2010; L. Lenci et al., J. Phys. B 45, 215401, 2012; L. Lenci et al., Phys. Rev. A 89, 043836, 2014; E. Breschi et al., Appl. Phys. B 115).

In prior art, a magnetometer has been described based on the free precession of the spins of alkali atoms in a vapor cell (U.S. Pat. No. 8,421,455 B1), where the precession was monitored through non-linear magneto-optical rotation. The free-precession magnetometer concept is commonly employed in proton magnetometers and by the low-field Nuclear Magnetic Resonance (NMR) community and has been chosen in applications that require high accuracy (Z. Grujić et al., Euro. Phys. J. D 69, 135, 2015; S. Afach, Opt. Expr. 23, 22108, 2015; H.-C. Koch et al., Eur. Phys. J. D 69, 202, 2015).

In noisy ambient field environments, it is often advantageous to measure the magnetic gradient field rather than the actual magnetic field itself, since the gradient field is often much more stable and can reveal information about close sources, while suppressing noise from distant sources. Gradiometers based on optically-pumped magnetometer with baselines of several centimeters have been developed by subtracting the outputs of two optically-pumped magnetometers (U.S. Pat. No. 7,573,264 B2; Affolderbach, C. et al., Appl. Phys. B, 75, 605, 2002; S. Trojanowski and M. Ciszek, Review of Scientific Instruments 79, 104702, 2008; Johnson, C., Schwindt, P. D. D. & Weisend, M., Appl. Phys. Lett. 97, 243703, 2010; Wyllie, R., et al., Phys. Med. Biol. 57, 2619, 2012; Sheng, D., et al., Appl. Phys. Lett. 110, 031106, 2017).

The gradient field optically pumped magnetometer (GF-OPM) of the present invention, consists of two alkali vapor cells, or sets of alkali atoms contained in some manner, separated by a distance referred to as the baseline of the gradiometer. Instead of passing the pump/probe beam through just one contained locations or cells of atoms, it passes through two or both contained locations or cells consecutively. After both spin-ensembles have been pumped simultaneously, the holding field is suddenly switched off and the spins in both cells precess at their respective Larmor frequencies ω_{L1}=γB₁ and ω_{L2}=γB₂, where B₁ and B₂ represent the magnetic fields at the locations of the two cells, respectively. The two vapor cells modulate the probe beam at both frequencies, and a beat can be seen on the photodiode at the difference frequency Δω=γ·|B₁−B₂|=γ·∇B·Δ, where Δ is the baseline. The beat frequency is therefore directly proportional to the magnetic field gradient ∇B and can be extracted independently even without the knowledge of independent magnetometer outputs. The advantage of this method is that the beat note frequency depends only on the gradient field and is therefore immune to parameter drifts such as probe laser frequency or amplitude.

As such, what is described and claimed is, a gradient field optically pumped magnetometer (GF-OPM) device comprising atoms confined in at least two locations; a means to spin polarize the atoms in the at least two locations; a means to extract a beat note signal from the Larmor precession signal in the at least two locations; a means to measure the frequency or phase of the beat note signal; and a means to create a gradiometer output based on frequency or phase of the beat note signal. In another embodiment, a method for measuring a magnetic field is provided and comprises the steps of: a) spin-polarizing atoms in at least two locations; b) inducing Larmor precession in the atoms in the at least two locations; c) detecting the Larmor precession signal from the atoms in the at least two locations; d) extracting a beat note signal of the Larmor precession signal from the atoms in the at least two locations; e) measuring the frequency or phase of the beat note signal; and f) creating and output signal of the gradiometer based on the frequency or phase of the beat note signal.

### BRIEF DESCRIPTION OF THE DRAWINGS

FIG. 1 is a schematic diagram illustrating the invention.

FIG. 2 is a schematic diagram illustrating several components of one embodiment of the invention.

FIG. 3 is a schematic diagram illustrating several components of a second embodiment of the invention.

FIG. 3 is a schematic diagram illustrating the setup used in the example.

FIG. 4 is a schematic diagram of an example system and method.

FIG. 5A is the measured output from just one magnetometer.

FIG. 5B is the measured output of the gradiometer before low-pass filtering

FIG. 5C is the measured output of the gradiometer after low-pass filtering

Before explaining the disclosed embodiments of the present invention in detail, it is to be understood that the invention is not limited in its application to the details of the particular arrangement shown, since the invention is capable of other embodiments. Also, the terminology used herein is for the purpose of description and not of limitation.

### DETAILED DESCRIPTION OF THE INVENTION

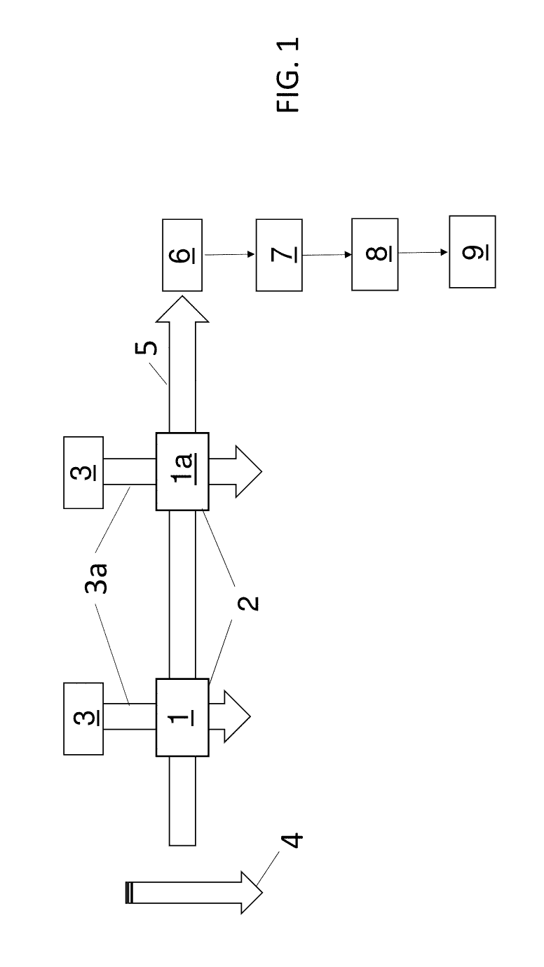

FIG. 1 is a schematic diagram illustrating the invention. Atoms with a transition frequency dependent on the strength of a magnetic field, are confined in at least two locations 1, 1a. The confinement can be created by vapor cells 2 with transparent walls, by light beams inside a vacuum, or by a solid environment. These atoms may be alkali or helium atoms, for example. The atoms, such as alkali atoms, are confined in at least two locations 1, la. The two locations 1, la define the sites of the magnetic field measurements. For a gradiometer of first order, two location are sufficient, but the scheme could be extended to gradiometers of higher order, and therefore more than two locations of atoms may be employed. A means to spin polarize the atoms in the at least two locations is provided. This may be a short pulse of circularly-polarized pump light 3 used to create a pump laser beam 3a. The photons of the pump laser beam 3a are absorbed by the atoms 1, 1a and the polarization is transferred from the photons to the atoms. After the atomic spins of the atoms are sufficiently polarized, a means for inducing Larmor spin precession is activated. This could be accomplished by turning off the pump light 3, or the pump laser beam 3a may be detuned out of resonance with the atoms. A single beam may be used and absorbed by the atoms in the different locations. A magnetic field 4, parallel to the direction of the pump laser beam 3a, may be employed, and would be turned off at the same time that the pump light 3 is turned off, or the pump laser beam 3a is detuned out of resonance with the atoms, causing spin-precession of the atomic spins around the ambient magnetic field. Spin precession can also be achieved by driving the spins on resonance with the Larmor precession frequency or its harmonics or subharmonics by means of light or an applied magnetic field. This spin precession is detected with a probe laser beam 5 for example. The probe laser beam 5 carries information about the magnetic fields at both locations 1 and 1a in that the precession frequencies are imprinted on the phase, polarization, or amplitude of the probe laser beam 5. A single light or laser beam may be employed to spin polarize and detect and extract the beat note signal. The probe laser beam 5 is detected with a photodetector 6. The probe laser beam 5 and the photodetector 6 provide a means to extract a signal from the atoms in the at least two locations that contains information about the magnetic field gradient, and an electronic signal processor 7 and/or low pass filter generates and filters a beat note signal from the two Larmor precession frequencies. This frequency is counted or measured with a frequency counter 8, which could be, but is not limited to being a frequency or phase detector. Finally, a gradiometer output is created by a processor 9 from the frequency of the beat note signal. Measurement can be on-going such that a new beat note signal is generated periodically or consistently. Spin-polarization and detection of the Larmor precessions can occur simultaneously. Alternately, spin-polarization could be accomplished followed by detection. This process can be repeated over and over to monitor over time.

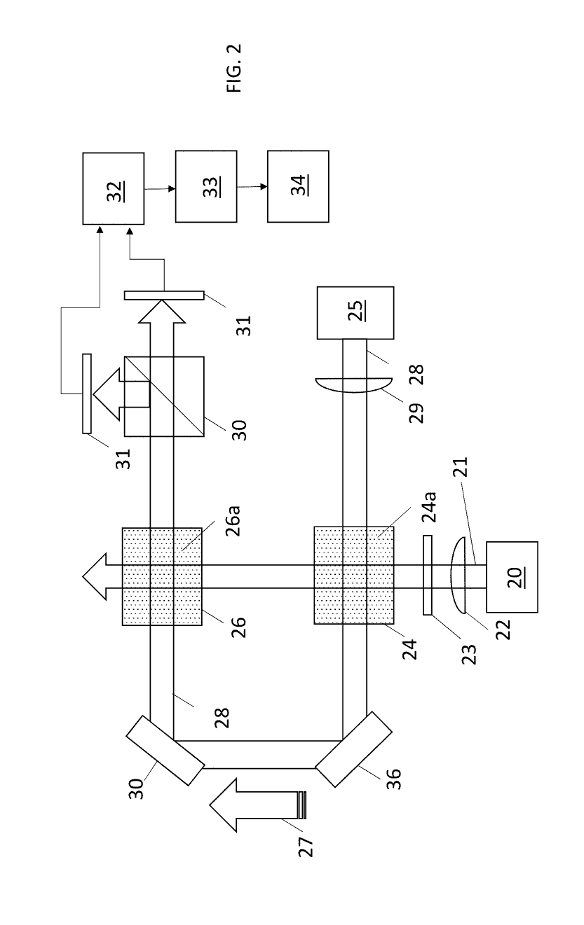

FIG. 2 represents a schematic diagram of one embodiment of the system and method for measuring gradient magnetic fields with a GF-OPM. In FIG. 2, a first pump laser 20 emits a pump light beam 21 at a wavelength equal to that of an optical resonance in alkali atoms 24a and 26a. The light is collimated with a lens 22 and elliptically polarized with a quarter-wave plate 23. The light enters a vapor cell 24, which confines a vapor of alkali atoms 24a. The light beam then passes a second vapor cell 26 also containing a vapor of alkali atoms 26a. The circular part of the light spin-polarizes the atoms in both vapor cells 24 and 26 in the presence of a magnetic holding field 27 in the direction of the laser beam. When the atomic spins in the atoms are polarized, the holding field 27 is switched off and the atomic spins precess around the ambient magnetic fields at the locations of the vapor cells, 24 and 26, at their respective Larmor precession frequencies. A second probe laser 25 emits a probe light beam 28 with a wavelength detuned from an optical transition in the atoms, 24a and 26a. The light is collimated with a lens 29 and passes both vapor cells 24 and 26 consecutively via reflection off two mirrors 30 and 36. The polarization and amplitude of the probe light beam 28 is modulated at both Larmor precession frequencies. The polarization modulations are detected with a balanced polarimeter consisting of a polarizing beamsplitter 30, two photodiodes 31, and a differential transimpedance amplifier 32. The beat note signal is extracted and passed through a low-pass filter 33. The frequency of the beat note signal is determined with a frequency counter 34. Alternatively, phase-sensitive detection could be used. The output of the frequency counter is a measure of the magnetic field gradient between the two vapor cells. Ambient magnetic field fluctuations and environment noise is rejected, since it shifts the frequencies in both locations by the same amount, but does not affect the beat frequency.

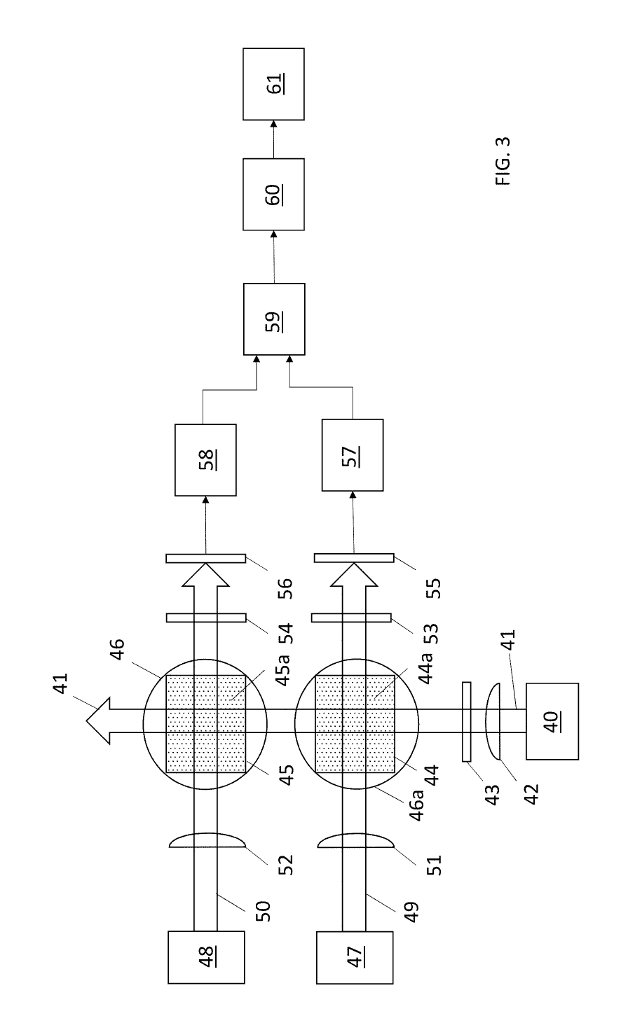

FIG. 3 is a schematic diagram illustrating a second embodiment of the invention. A pump diode laser 40 emits a light beam 41 with a wavelength resonant with atoms 44a and 45a confined in two vapor cells 44 and 45. The light beam 41 is collimated with a lens 42 and circularly polarized with a quarter-wave plate 43. The light is used to optically create a spin-polarization in the atoms 44a and 45a in both vapor cells 44 and 45. Field coils 46 and 46a around the vapor cells 44 and 45 resonantly drive the spin precessions in the two atomic ensamples. The precession frequencies are direct measures of the magnetic fields at the locations of the atoms 44a and 45a. Two probe lasers 47 and 48 are used to probe the spin precessions frequencies. They emit light beams 49 and 50 at wavelengths slightly detuned from the atomic transitions. The light beams 49 and 50 are collimated with a lens each 51 and 52. When the beams pass the vapor cells 44 and 45 the precessing atoms 44a and 45a modulate the polarization of the light beams 49 and 50 at the precession frequencies. Two polarizers 53 and 54 convert the polarization modulation of the light into amplitude modulation. The light beams are detected with two photodiodes 55 and 56, which are creating electrical signals oscillating at the two precession frequencies. The signals are amplified with two transimpedance amplifiers 57 and 58. A mixer 59 beats the signals and creates a component that oscillates at the difference frequency which is a direct measure of the field gradient. Higher frequency components are removed with a low-pass filter 60 and the difference frequency is monitored with a frequency counter 61, which creates an output signal based on this frequency. This signal is a measure of the magnetic field gradient between the two vapor cell locations.

### EXAMPLES

### Example 1

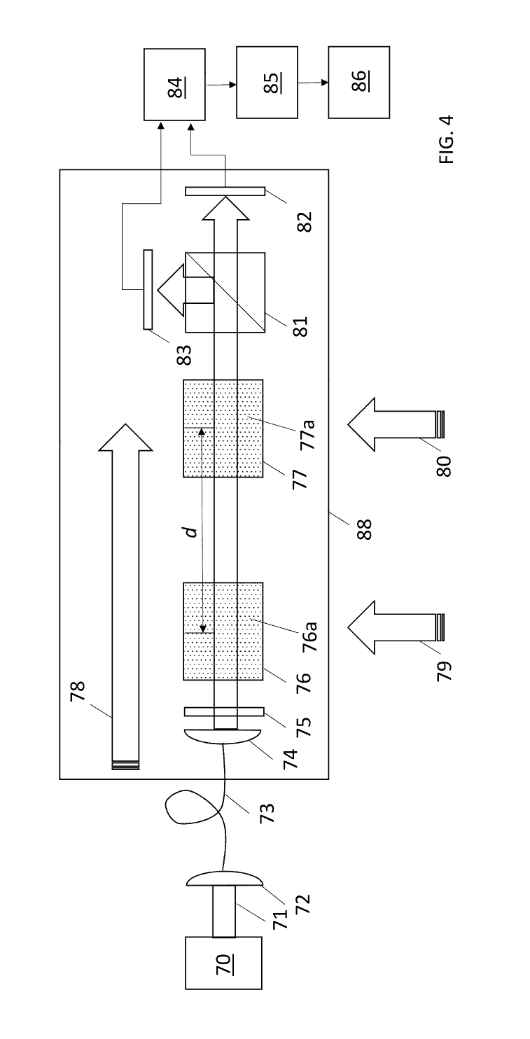

As an example, a simple OPM gradiometer prototype was built as shown in FIG. 4. The gradiometer consists of two alkali vapor cells 76 and 77 separated by a distance, d, referred to as the baseline of the gradiometer. Light from a diode laser 70 at 795 nm was used to optically pump the electron spins of rubidium atoms 76a, 77a and simultaneously probe their free spin precession. The light beam 71 from the laser 70 was coupled into a polarization-maintaining optical fiber 73 with a lens 72 and delivered to the physics package 88. A physics package 88, as used herein, comprised the physical components as opposed to the electrical/electronic components of the system. In this case, the items within the physics package 88 were built and then housed in a single confined unit. The light was expanded and collimated with a lens 74 to a 2 mm diameter beam. A quarter-wave plate 75, with its optical axis aligned to 22.5° with respect to the input polarization of the light produced, elliptically polarized the light. The elliptically polarized light then passed through the two vapor cells 76 and 77 separated by roughly 5 cm. The dimensions of the vapor cells were 3 mm×3 mm×3 mm. Each vapor cell, 76 and 77, contained a small droplet of ⁸⁷Rb metal and nitrogen buffer gas. After passing through the vapor cells 76, 77, the transmitted light was analyzed with a balanced polarimeter. The polarimeter consisted of a polarizing beamsplitter 81, which split nearly equal amounts of light onto two photodiodes 82 and 83. The output signals of the two photodiodes were subtracted from each other in a subtracting trans-impedance amplifier 84. Next, the wavelength of the laser was detuned to the side of the atomic resonance. A solenoid type coil 78 was wrapped around the outer surface of the magnetometer to produce a magnetic field a few times stronger than Earth's field in the direction of the laser beam inside the physics package 88. The magnetometer was oriented roughly perpendicular to the Earth's field during measurement.

When the solenoid was energized, the circular part of the laser light polarized a significant fraction of the atoms through optically pumping to the F=2, m_{F}=2 ground state. Once the optical pumping process reached an equilibrium, and the current through the solenoid 78 was cut-off in less than 1 μs. This non-adiabatic cut-off caused the rubidium atoms in each cell to start precessing about the Earth's field at their respective Larmor frequencies. The precessing spins induced an oscillating polarization rotation in the linearly-polarized part of the light. The spins in both cells precess at their respective Larmor frequencies ω_{L1}=γB₁ and ω_{L2}=γB₂, where B₁ and B₂ represent the magnetic fields at the locations of the two cells, respectively. The two vapor cells modulated the probe beam at both frequencies, and a beat was on the photodiode at the difference frequency Δω=γ·|B₁−B₂|=γ·∇B·Δ, where Δ is the baseline. The beat frequency was therefore directly proportional to the magnetic field gradient ∇B and was extracted independently, even without the knowledge of independent magnetometer outputs.

In the presence of a magnetic gradient, the two cells experienced slightly different magnetic fields 79 and 80, and therefore, the atoms precessed at slightly different frequencies. The polarimeter output produced a beat note signal with a frequency ω_{beat} proportional to the magnitude of the gradient field ∇B: ω_{beat}=γ·∇B·Δ. Here, γ was the gyromagnetic ratio and Δ is the gradiometer baseline. The signal was rectified or squared and then a low-pass filter 85 was used to remove the high-frequency oscillations corresponding to the Larmor frequencies of the atoms, leaving behind only the beat note. The phase or frequency of the beat note was measured with a counter 86, which functions as the output of the gradiometer. For gradiometer operation, only the filtered slow beat frequency must be measured. The information related to individual noisy magnetometer outputs (individual precession frequencies in two cells) has no relevance and can be discarded entirely.

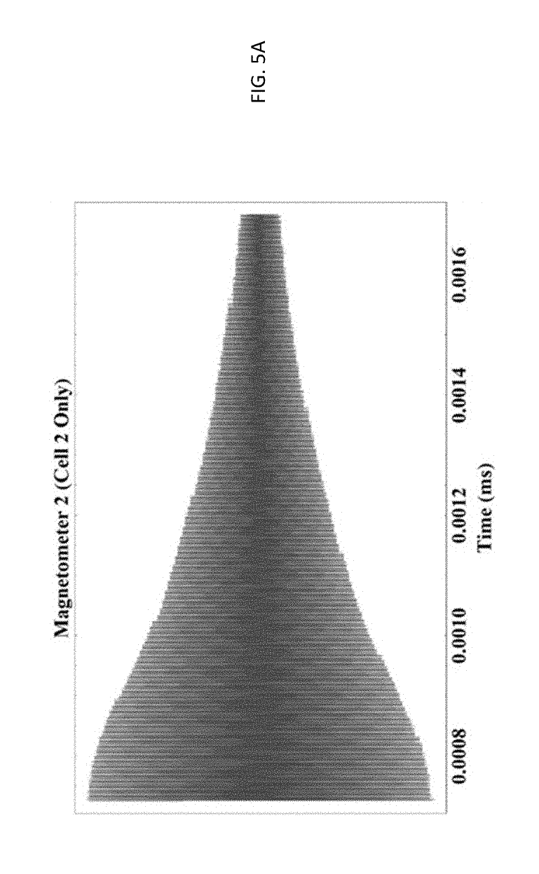

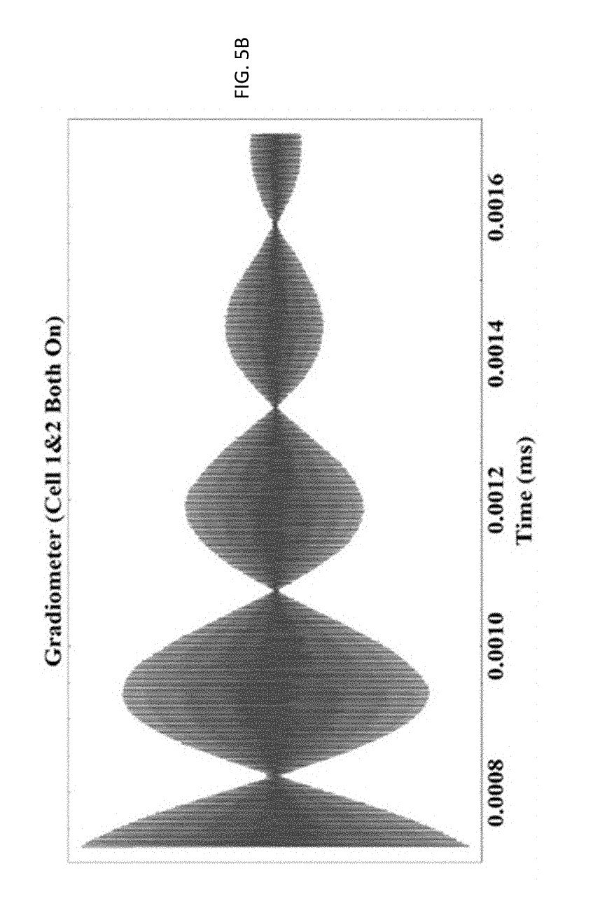

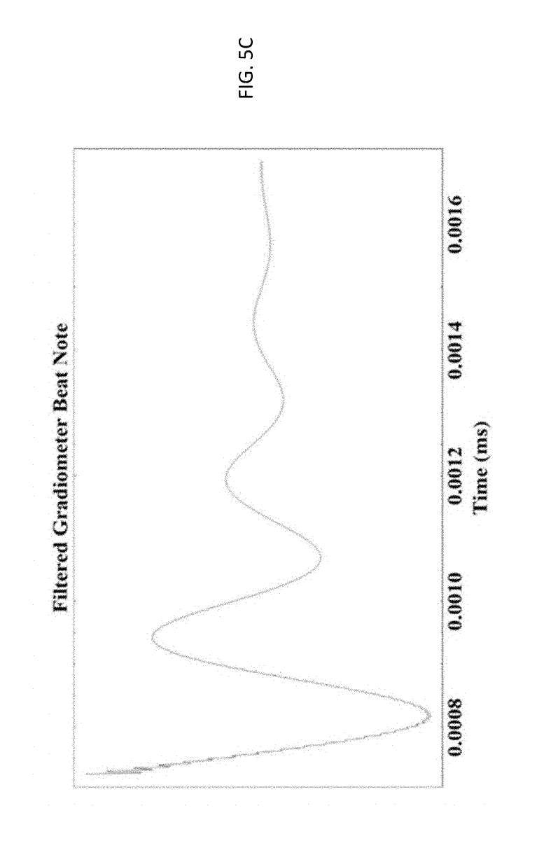

The experimentally recorded precession signal from one of the cells is shown in FIG. 5A, as well as the beat note signal before low-pass filtering FIG. 5B, and after low-pass filtering FIG. 5C. A bias coil or permanent magnet near one of the vapor cells can be used to artificially adjust the magnitude of the background gradient field such that the beat note completes about one or more full oscillations within the measurement period.

Although the present invention has been described with reference to the disclosed embodiments, numerous modifications and variations can be made and still the result will come within the scope of the invention. No limitation with respect to the specific embodiments disclosed herein is intended or should be inferred. Each apparatus embodiment described herein has numerous equivalents.

What is claimed is:

1. A gradient field optically pumped magnetometer (GF-OPM) device comprising:
a) atom sets confined in at least two locations and contained in a housing of the gradient field optically pumped magnetometer (GF-OPM) device;
b) a means to spin polarize the atom sets in the at least two locations;
c) a single optical light beam passing through atom sets in the at least two locations, wherein the single optical light beam is used to detect and carry a Larmor spin precession signal of each of the atom sets in the at least two locations;
d) a means to extract a beat note signal from the single optical light beam carrying the Larmor precession signal of each of the atom sets from the at least two locations, wherein the beat note signal is based on a difference between the Larmor spin precession signal of each of the atom sets;
e) a means to measure a frequency or a phase of the beat note signal; and
f) a means to create a gradiometer output based on the frequency or the phase of the beat note signal.

2. The gradient field optically pumped magnetometer (GF-OPM) device of claim 1, where the atom sets comprise alkali atoms.

3. The gradient field optically pumped magnetometer (GF-OPM) device of claim 1, where the atom sets are confined in vapor cells.

4. The gradient field optically pumped magnetometer (GF-OPM) device of claim 1, wherein the means to spin polarize the atom sets is a light beam.

5. (canceled)

6. The gradient field optically pumped magnetometer (GF-OPM) device of claim 1, wherein the single light beam is used as a means to spin polarize the atom sets and a means to detect and carry the Larmor spin precession signal.

7. The gradient field optically pumped magnetometer (GF-OPM) device of claim 1 further comprising at least one additional optical light beam.

8. (canceled)

9. The gradient field optically pumped magnetometer (GF-OPM) device of claim 1 further comprising at least one means for creating a magnetic field.

10. A method for measuring a magnetic gradient field with an optically pumped gradiometer, the method comprising the step of
a) spin-polarizing atom sets confined in at least two locations within a housing of the optically pumped gradiometer;
b) inducing Larmor precession in the atom sets in the at least two locations;
c) detecting the Larmor precession signal from the atom sets in the at least two locations using a single optical light beam;
d) extracting a beat note signal of the difference between the Larmor precession signal from the atom sets in the at least two locations with the single optical light beam;
e) measuring one or more of a group comprising a frequency and phase of the beat note signal; and
f) creating an output signal of the gradiometer based on one or more of a group comprising the frequency and phase of the beat note signal.

11. The method of claim 10, where the atom sets comprise alkali atoms.

12. The method of claim 10, where the atom sets are confined in the at least two locations by vapor cells.

13. The method of claim 10, where the atom sets are spin polarized with light.

14. The method of claim 10, where inducing the Larmor precession in the atom sets alters at least one of the group consisting of, the amplitude, phase, and polarization of the single optical light beam passing through the atom sets.

15. The method of claim 10, where the Larmar precession of the atom sets is induced without the application of fields resonant with one or more of a group chosen from a Larmor precession frequency and the Larmor precession frequency harmonics, and subharmonics of the atom sets.

16. The method of claim 10, where Larmor precession of the atom sets is induced through the application of fields resonant with one or more of the group selected from a Larmor frequency of the atom sets, and the Larmor frequency's harmonics, and subharmonics.

17. The method of claim 10, where a single laser is used in the step of spin polarizing atom sets and in the step of detecting the Larmor precession signal.

18. The method of claim 10, wherein the steps of spin polarizing atom sets and the steps of detecting the Larmor precession signal occur simultaneously.

19. The method of claim 10, wherein the step of spin polarizing atom sets is accomplished before the step of detecting the Larmor precession signal.

20. A system to measure the magnetic field gradient, the system comprising:
a) atoms confined in at least two locations within a single housing;
b) a means to spin polarize electron spins of the atoms confined in the at least two locations;
c) a means to induce a free Larmor spin precession of the electron spins of the atoms in the at least two locations;
d) at least one optical light beam passing through the atoms in the at least two locations, wherein the at least one optical light beam is used to detect and carry free Larmor spin precession signals of the atoms in the at least two locations;
e) a means to extract a beat note signal using a difference in the Larmor precession signals of the atoms in the at least two locations;
f) a means to measure one or more attributes of the beat note signal including a frequency and a phase of the beat note signal; and
g) a means to create a gradiometer output based on one or more attributes of the beat note signal.
